(19) United States
(12) Patent Application Publication
(10) Pub. No.: US 2025/0089498 A1
(43) Pub. Date: Mar. 13, 2025

(54) DISPLAY APPARATUS

(71) Applicant: SAMSUNG DISPLAY CO., LTD., YONGIN-SI (KR)

(72) Inventors: Dongjin Moon, YONGIN-SI (KR); Wonkyu Kwak, YONGIN-SI (KR); Junseok Min, YONGIN-SI (KR)

(21) Appl. No.: 18/752,888

(22) Filed: Jun. 25, 2024

(30) Foreign Application Priority Data
Sep. 11, 2023 (KR) 10-2023-0120737
Jan. 2, 2024 (KR) 10-2024-0000488

(51) Int. Cl. H10K 59/131; H10K 59/40; H10K 59/80

(52) U.S. Cl. CPC H10K 59/131; H10K 59/40; H10K 59/873

(57) ABSTRACT

A display apparatus includes a substrate, a pixel circuit layer located on the substrate, and a touch sensing layer located on the pixel circuit layer, and comprising a first metal wiring, an insulating member layer located on the first metal wiring, and a second metal wiring located on the insulating member layer. The second metal wiring comprises an opening exposing a top surface of the insulating member layer, and the opening of the second metal wiring is located at a first region where the second metal wiring and the first metal wiring overlap each other in a plan view.

### CROSS-REFERENCE TO RELATED APPLICATION

This application is based on and claims priority under 35 U.S.C. § 119 to Korean Patent Application Nos. 10-2023-0120737 and 10-2024-0000488, respectively filed on Sep. 11, 2023 and Jan. 2, 2024, in the Korean Intellectual Property Office, the disclosures of each of which are incorporated by reference herein in their entirety.

### BACKGROUND

### 1. Field

One or more embodiments relate to a display apparatus, and more particularly, to a display apparatus capable of minimizing dark patterns generated by a metal wiring of a touch sensing layer.

### 2. Description of the Related Art

A display apparatus receives information about an image and displays the image. A display apparatus is used as a display for a small product such as a mobile phone or as a display for a large product such as a television.

A display apparatus includes a plurality of pixels that emit light by receiving an electrical signal to display an image to the outside. Each pixel includes a light-emitting device. For example, an organic light-emitting display apparatus includes an organic light-emitting diode (OLED) as a light-emitting device. In an organic light-emitting display apparatus, a thin-film transistor and an OLED are formed on a substrate, and the OLED emits light by itself.

A display apparatus includes a window member, and the window member may include a transmitting area, a light-blocking area covering an edge (or extending along the edge), and an adjacent area between the transmitting areas.

### SUMMARY

One or more embodiments include a display apparatus capable of minimizing dark patterns generated by a metal wiring of a touch sensing layer. However, the embodiments are examples and do not limit the scope of the disclosure.

Additional aspects will be set forth in part in the description which follows and, in part, will be apparent from the description, or may be learned by practice of the presented embodiments.

According to an aspect of the present disclosure, a display apparatus includes a substrate, a pixel circuit layer located on the substrate, and a touch sensing layer located on the pixel circuit layer, and comprising a first metal wiring, an insulating member layer located on the first metal wiring, and a second metal wiring located on the insulating member layer. The second metal wiring comprises an opening exposing a top surface of the insulating member layer, and the opening of the second metal wiring is located at a first region where the second metal wiring and the first metal wiring overlap each other in a plan view.

The second metal wiring may further include a first layer including a first metal, a second layer including a second metal and located on the first layer, and a third layer including the first metal and located on the second layer.

An inner surface of the opening may include a first inner side surface of the first layer, a second inner side surface of the second layer, and a third inner side surface of the third layer. The first inner side surface, the second inner side surface, and the third inner side surface are coplanar with other to form the inner surface of the opening.

The opening may include a plurality of openings, wherein each of the plurality of openings has a circular shape or an elliptical shape in a plan view.

The touch sensing layer may further include a third metal wiring located on a same layer and having a same layer structure as the first metal wiring.

The insulating member layer may include a contact hole passing through the insulating member layer and located at a second region where the third metal wiring and the second metal wiring overlap each other.

The third metal wiring is connected to the second metal wiring via the contact hole.

The second metal wiring and the third metal wiring may be configured to transmit a same signal, and the second metal wiring and the first metal wiring may be configured to transmit different signals.

The display apparatus may further include a window member located on the touch sensing layer. The window member may include a transmitting area, a light-blocking pattern covering an edge of the window member, and an adjacent area therebetween.

The substrate may include a display area where an image is displayed and a peripheral area covered by the light-blocking pattern and the adjacent area, the display area is covered by the transmitting area, and the opening is located in the adjacent area in a plan view.

The contact hole may be located in the adjacent area in a plan view.

A first diameter of the opening may be greater than a second diameter of the contact hole in a plan view.

The opening is provided in plural, and the contact hole may be provided in plural, a first distance between two adjacent openings among the plurality of openings may be less than a second distance between two adjacent contact holes among the plurality of contact holes in a plan view, and the first distance and the second distance may be measured in a same direction.

The second metal wiring may further include a first sub-metal wiring disposed in the peripheral area and a second sub-metal wiring disposed in the adjacent area.

The first region may be an area where the second sub-metal wiring and the first metal wiring intersect each other in a plan view.

The display apparatus may further include a window member located on the touch sensing layer, wherein the window member includes a light-blocking pattern covering an edge of the window member, wherein the first sub-metal wiring overlaps the light-blocking pattern in a plan view.

The third metal wiring may include a 2-1 sub-layer including a first metal, a 2-2 sub-layer including a second metal and located on the 2-1 sub-layer, and a 2-3 sub-layer including the first metal and located on the 2-2 sub-layer.

The 2-3 sub-layer is connected to the second metal wiring through the contact hole.

The pixel circuit layer may include at least one light-emitting device and a thin-film encapsulation layer on the at least one light-emitting device.

The touch sensing layer may be located on the thin-film encapsulation layer.

### BRIEF DESCRIPTION OF THE DRAWINGS

The above and other aspects, features, and advantages of certain embodiments will be more apparent from the following description of exemplary and non-limiting embodiments taken in conjunction with the accompanying drawings, in which:

FIG. 1 is an exploded perspective view illustrating a display apparatus, according to an embodiment of the present disclosure;

FIG. 2 is a plan view illustrating the display apparatus of FIG. 1 according to an embodiment of the present disclosure;

FIG. 3 is an equivalent circuit diagram illustrating a pixel of the display apparatus of FIG. 1 according to an embodiment of the present disclosure;

FIG. 4 is a cross-sectional view illustrating one pixel and surroundings thereof in the display apparatus of FIG. 1 according to an embodiment of the present disclosure;

FIG. 5 is a perspective view illustrating a touch sensing layer of a display panel of FIG. 1 according to an embodiment of the present disclosure;

FIG. 6 is a plan view illustrating a portion A of FIG. 2 according to an embodiment of the present disclosure;

FIG. 7 is a cross-sectional view taken along line A-A′ of FIG. 6 according to an embodiment of the present disclosure;

FIG. 8 is a cross-sectional view taken along line A-A′ of FIG. 6 according to an embodiment of the present disclosure;

FIG. 9 is a cross-sectional view taken along line B-B′ of FIG. 6 according to an embodiment of the present disclosure;

FIG. 10 is a cross-sectional view taken along line B-B′ of FIG. 6 according to an embodiment of the present disclosure;

FIGS. 11 to 13 are plan views illustrating an example of the portion A of FIG. 2 according to an embodiment of the present disclosure; and

FIG. 14 is a plan view illustrating an example of a portion of a display apparatus according to a comparative example, which corresponds to the portion A of FIG. 2.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

It will be understood that when a component, such as a layer, a film, a region, or a plate, is referred to as being “on” another component, the component may be directly on the other component or intervening components may be present therebetween. It will be understood that when a component, such as a layer, a film, a region, or a plate, is referred to as being “under” another component, the component may be directly under the other component or intervening components may be present therebetween.

Sizes of components in the drawings may be exaggerated or reduced for convenience of explanation. For example, because sizes and thicknesses of components in the drawings are arbitrarily illustrated for convenience of explanation, the disclosure is not limited thereto. That is, for convenience of explanation, sizes, thicknesses, and ratios of components in the drawings may be exaggerated and/or simplified for clarity. Accordingly, spatially relative terms such as “beneath”, “below”, “lower”, “under” “above”, and “upper” may be used to easily describe one element or feature's relationship with another element or feature.

In the specification, it will be understood that terms used to describe spaces, directions, etc. are intended to encompass different directions or viewpoints in addition to the spaces or directions shown in the drawings. For example, when a device or a component in the drawings is turned over, the device described as “below” may be may be otherwise oriented (e.g., rotated by 90 degrees or the opposite direction). For example, when a device or a component in the drawings is turned over, the device described as “above” may be otherwise oriented (e.g., rotated by 90 degrees or the opposite direction). Accordingly, the terms “below” and “above” may include both orientations of above and below. A device or a component may be otherwise oriented and the spatially relative descriptors used herein should be interpreted accordingly.

In the specification, a process order or a method order in the description of a process or manufacturing method may be different from the described order. For example, two consecutively described processes may be performed substantially at the same time or performed in an order opposite to the described order.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the specification, the terms “first”, “second”, and “third” may be used to describe specific components, and the terms “first”, “second”, and “third” may be used to distinguish one component from another.

When one component is referred to as “connected to” or “coupled to” another component, it may be directly connected to or coupled to the other component or one or more intervening component may be present therebetween.

Likewise, when one component is “electrically connected” to another component, the component and the other component may be directly and electrically connected, or may be indirectly and electrically connected through a conductive component.

It will be understood that when one component is referred to as being “between” two components, it is the only component located between the two components or an intervening component other than the component is located between the two components.

The terminology used herein is for the purpose of describing particular embodiments only and is not intended to be limiting of the disclosure. The singular terms “a” and “an” used herein are intended to include the plural forms as well unless the context clearly indicates otherwise.

For example, the terms “comprises”, “comprising”, “includes”, and “including” specify the presence of the described feature, integer, step, operation, element, and/or component, but do not preclude the presence or addition of one or more other features, integers, steps, operations, elements, components, and/or groups thereof.

For example, the term “and/or” includes any and all combinations of one or more of the associated listed items. For example, the expression “A and/or B” indicates A, B, or A and B. The expression “at least one of” may be used to indicate one or more components among a plurality of components. For example, the expression “at least one of a, b, and c” or “at least one selected from the group consisting of a, b, and c” may indicate “a”, “b”, “c”, “a, b”, “b, c”, “a, c”, or “a, b, c”.

For example, the terms such as “substantially” and “about” and similar terms are used as terms of approximation rather than terms of degree, and may be intended to account for inherent deviations in measured or calculated values that would be recognized by one of ordinary skill in the art. For example, the use of the term “may” or “can” when describing embodiments may refer to one or more embodiments disclosed in the specification.

For example, in the specification, when one layer has the “same layer structure” as another layer, it may mean that a plurality of layers included in the one layer may be included in the other layer in the same order. For example, a plurality of layers included in one layer and a plurality of layers included in another layer may include the same material and may be formed in the same order.

Electronic or electric devices and/or other related devices or components (e.g., some of various modules) according to embodiments described herein may be implemented by using any suitable hardware, firmware (e.g., application-specific integrated circuit), software, or a combination of software, firmware, and hardware. For example, various components of these devices may be formed on one integrated circuit (IC) chip or separate IC chips. Further, various components of these devices may be formed on a flexible printed circuit film, a tape carrier package (TCP), a printed circuit board (PCB), or formed on one substrate. Further, various components of these devices may be processes or threads, running on one or more processors, in one or more computing devices, executing compute program instructions, and interacting with other system components for performing various functions described herein.

The computer program instructions are stored in a memory that may be implemented in a computing device using a standard memory device such as a random-access memory (RAM). The computer program instructions may also be stored in other non-transitory computer-readable media such as a CD-ROM and a flash drive. One of ordinary skill in the art should recognize that functions of various computing devices may be combined or integrated into a single computing device or that a function of a specific computing device may be distributed across one or more other computing devices without departing from the spirit and scope of the embodiments.

Hereinafter, a display apparatus according to an embodiment will be described in detail based on the above description.

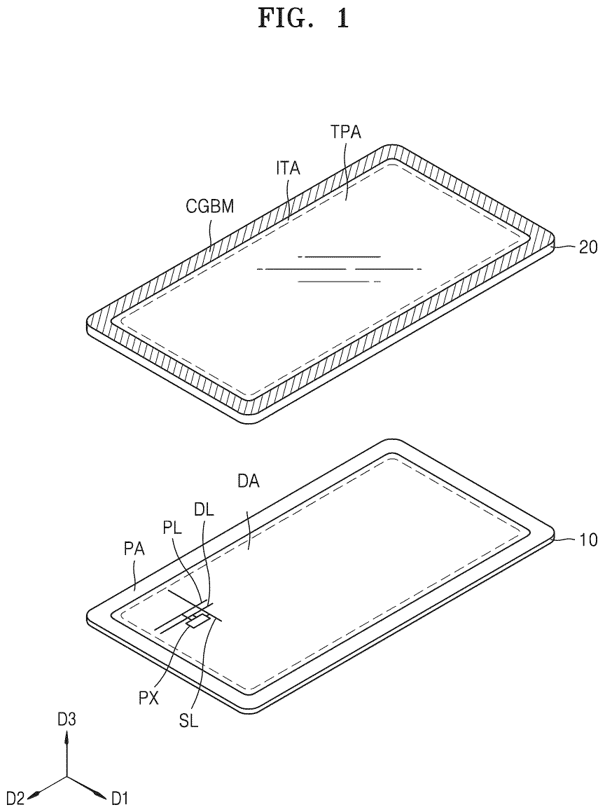

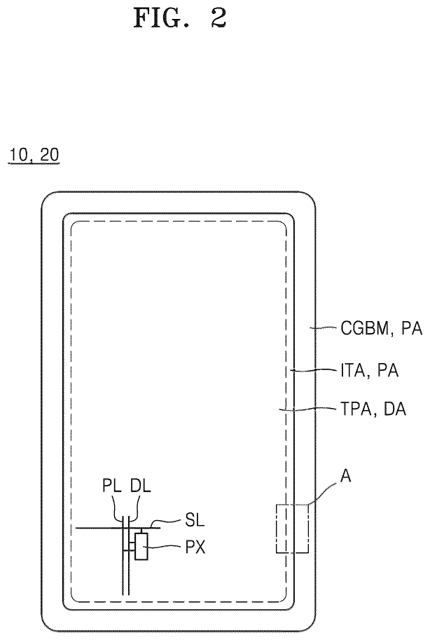

FIG. 1 is an exploded perspective view illustrating a display apparatus according to an embodiment. FIG. 2 is a plan view illustrating the display apparatus of FIG. 1.

As shown in FIGS. 1 and 2, a display apparatus according to an embodiment may include a display panel 10 and a window member 20 located on the display panel 10. The display apparatus may be any device including the display panel 10. For example, the display apparatus may be any of various devices such as a smartphone, a tablet, a laptop, a television, and a billboard. The display apparatus according to an embodiment includes thin-film transistors and a capacitor, and the thin-film transistors and the capacitor may be implemented by conductive layers and insulating layers.

The display panel 10 includes a display area DA and a peripheral area PA located outside the display area DA. The display area DA has a rectangular shape in FIG. 1. However, the disclosure is not limited thereto. In an embodiment, the display area DA may have any of various shapes such as a circular shape, an elliptical shape, a polygonal shape, and a specific shape.

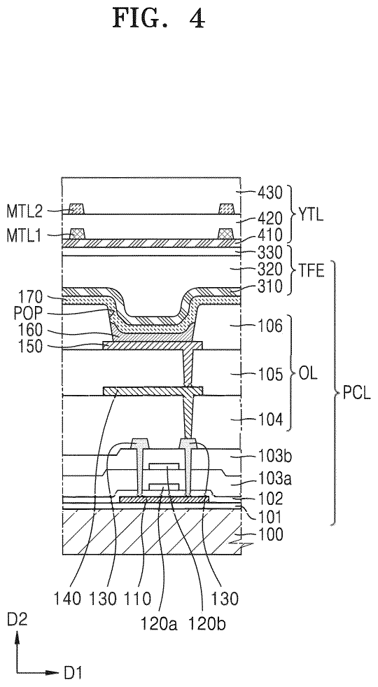

The display area DA is a portion where an image is displayed, and a plurality of pixels PX may be located in the display area DA. Each pixel PX may include a display device such as an organic light-emitting device. Each pixel PX may emit, for example, red light, green light, or blue light. The pixel PX may be connected to a pixel circuit including a thin-film transistor (TFT) and a storage capacitor. The pixel circuit may be connected to a scan line SL through which a scan signal is transmitted, a data line DL that intersects the scan line SL and through which a data signal is transmitted, and a driving voltage line PL through which a driving voltage is supplied. The data line DL and the driving voltage line PL may extend in a second direction D2, and the scan line SL may extend in a first direction D1. In an embodiment, the first direction D1 and the second direction D2 may be parallel to an upper surface of a substrate 100 of FIG. 4, which will be described later.

The pixel PX may emit light having a luminance corresponding to an electrical signal from the pixel circuit that is electrically connected to the pixel PX. The display area DA may display a certain image through light emitted from the pixel PX. In an embodiment, the pixel PX may be defined as an emission area that emits light of any one of red, green, and blue colors.

The peripheral area PA may be a portion where the pixel PX is not located and an image is not displayed. A power supply wiring or the like for driving the pixel PX may be located in the peripheral area PA. Pads may be located in the peripheral area PA, and an integrated circuit device such as a driver IC or a printed circuit board including a driving circuit unit and the pads may be electrically connected to each other in the peripheral area PA.

The display panel 10 may include the substrate 100 (see FIG. 4), and the display panel 10 may include the display area DA and the peripheral area PA. The substrate 100 will be described below in detail.

In the display area DA, a plurality of transistors may be located. In the plurality of transistors, a first terminal of the transistor may be a source electrode or a drain electrode, and a second terminal may be an electrode different from the first terminal, according to a type (N-type or P-type) and/or an operating condition of the transistor. For example, when the first terminal is a source electrode, the second terminal may be a drain electrode.

The plurality of transistors may include a driving transistor, a data write transistor, a compensation transistor, an initialization transistor, and an emission control transistor. The driving transistor may selectively connect the driving voltage line PL to the organic light-emitting device. The data write transistor may be connected to the data line DL and the driving transistor. The data wire transistor may perform a switching operation of transmitting a data signal transmitted through the data line DL.

The compensation transistor may be turned on according to a scan signal received through the scan line SL to connect the driving transistor to the organic light-emitting device and compensate for a threshold voltage of the driving transistor.

The initialization transistor may be turned on according to a scan signal received through the scan line SL to transmit an initialization voltage to a gate electrode of the driving transistor and initialize the gate electrode of the driving transistor. The scan line connected to the initialization transistor may be a separate scan line different from the scan line connected to the compensation transistor.

The emission control transistor may be turned on according to an emission control signal received through an emission control line so that driving current flows through the organic light-emitting device (OLED).

The organic light-emitting device includes a pixel electrode (e.g., an anode) and a counter electrode (e.g., a cathode), and may receive a required voltage from the pixel electrode (e.g., the anode) and the counter electrode (e.g., the cathode). The organic light-emitting device may receive the driving current from the driving transistor to emit light and display an image.

In a plan view defined by the first direction D1 and the second direction D2, the window member 20 may be divided into a transmitting area TPA and a light-blocking area CGBM. The window member 20 may include the transmitting area TPA and the light-blocking area CGBM in a plan view.

The transmitting area TPA may be an area through which light is transmitted. The light-blocking area CGBM may be an area having a lower light transmittance than the transmitting area TPA. The light-blocking area CGBM may be adjacent to the transmitting area TPA. In the present embodiment, the light-blocking area CGBM may surround the transmitting area TPA. However, the present disclosure is not limited thereto. In an embodiment, the light-blocking area CGBM may be adjacent to only a part of an edge of the transmitting area TPA. In an embodiment, the transmitting area TPA may correspond to the display area DA. Accordingly, a user may easily view an image displayed in the display area DA through the transmitting area TPA.

The light-blocking area CGBM may be a light-blocking pattern covering an edge of the window member 20. The light-blocking area CGBM may be a light-blocking pattern covering an edge of the transmitting area TPA or an edge of a top surface of the transmitting area TPA. In an embodiment, the light-blocking pattern may include or may be formed of a black matrix and may include any of various materials that may absorb at least part of light. For example, the light-blocking pattern may include or may be formed of at least one of carbon black, graphite, a chrome-based material, a dye, a metallic reflective film, and a light-absorbing film. The light-blocking pattern may not only block or prevent reflection of external light, but also prevent internal reflection of light generated in a display device. In an embodiment, the light-blocking area CGBM may extend along the edge of the window member 20 and surround the transmitting area TPA. The light-blocking area CGBM may surround the entirety of the transmitting area TPA or may partially surround the transmitting area TPA.

The light-blocking pattern may further include a water-soluble salt. The water-soluble salt may be at least one of sodium, potassium, magnesium, manganese, aluminum, and calcium. The water soluble salt included in the light-blocking pattern may corrode a metallic material inside the display device together with moisture penetrating from the outside.

The window member 20 may further include an adjacent area ITA located between the transmitting area TPA and the light-blocking area CGBM in a plan view. The window member 20 may be divided into the transmitting area TPA, the adjacent area ITA, and the light-blocking area CGBM in a plan view defined by the first direction D1 and the second direction D2.

The adjacent area ITA and the light-blocking area CGBM may cover the peripheral area PA adjacent to the display area DA of the display panel 10. Accordingly, when a metal layer such as a wiring is located under the adjacent area ITA, there may be a problem that external light is reflected by the metal layer such as the wiring located under the adjacent area ITA. In an embodiment, the adjacent area ITA may be transparent like the transmitting area TPA and overlap a part of the peripheral area PA which is adjacent to the display area DA.

In a plan view, the display area DA of the display panel 10 may be covered by the transmitting area TPA, and the peripheral area PA of the display panel 10 may be covered by the adjacent area ITA and the light-blocking area CGBM. For example, the transmitting area TPA may overlap the display area DA, and the adjacent area ITA and the light-blocking area CGBM may overlap the peripheral area PA.

Hereinafter, an organic light-emitting display apparatus is described as the display apparatus according to an embodiment. The display apparatus of the disclosure is not limited thereto. In an embodiment, the display apparatus of the disclosure may be an inorganic light-emitting display apparatus, an inorganic electroluminescent (EL) display apparatus, or a quantum dot light-emitting display apparatus. For example, an emission layer of the display device included in the display apparatus may include an organic material or an inorganic material. In an embodiment, the display apparatus may include an emission layer and quantum dots located in a path of light emitted from the emission layer.

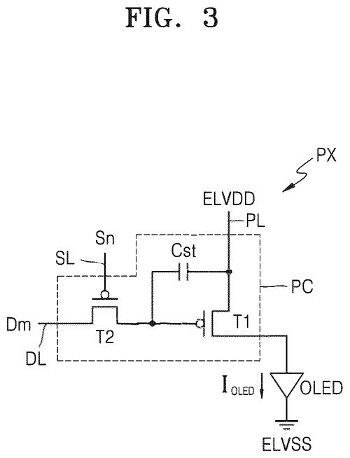

FIG. 3 is an equivalent circuit diagram illustrating a pixel of the display apparatus of FIG. 1.

In the description of FIG. 3, the same description as that made above will be omitted.

As shown in FIG. 3, each pixel PX includes a pixel circuit PC connected to a scan line SL and a data line DL and an organic light-emitting device OLED connected to the pixel circuit PC.

For example, the pixel circuit PC includes a driving thin-film transistor Td, a switching thin-film transistor Ts, and a storage capacitor Cst. The switching thin-film transistor Ts is connected to the scan line SL and the data line DL, and transmits a data signal Dm input through the data line DL to the driving thin-film transistor Td according to a scan signal Sn input through the scan line SL.

For example, the storage capacitor Cst is connected to the switching thin-film transistor Ts and a driving voltage line PL, and stores a voltage corresponding to a difference between a voltage received from the switching thin-film transistor Ts and a first power supply voltage ELVDD (or a driving voltage) supplied to the driving voltage line PL.

For example, the driving thin-film transistor Td may be connected to the driving voltage line PL and the storage capacitor Cst, and may control driving current flowing through the organic light-emitting device OLED from the driving voltage line PL in response to a value of the voltage stored in the storage capacitor Cst. The organic light-emitting device OLED may emit light having a certain luminance due to the driving current. For example, the organic light-emitting device OLED through which the driving current flows may emit light having a luminance corresponding to the driving current.

The organic light-emitting device OLED may receive a second power supply voltage ELVSS (or a common voltage). For example, the organic light-emitting device OLED may receive the second power supply voltage ELVSS (or common voltage) through a counter electrode (cathode), and the organic light-emitting device OLED may emit light having a certain luminance corresponding to the driving current driven according to a voltage difference between the first power supply voltage ELVDD (or driving voltage) and the second power supply voltage ELVSS (or common voltage).

The pixel circuit PC includes two thin-film transistors and one storage capacitor in FIG. 3. However, the disclosure is not limited thereto. For example, the pixel circuit PC may include two or more storage capacitors, and may include three or more thin-film transistors.

FIG. 4 is a cross-sectional view illustrating one pixel and surroundings thereof in the display apparatus of FIG. 1.

In the description of FIG. 4, the same description as that made above will be omitted.

The substrate 100 may include areas corresponding to the display area DA and the peripheral area PA outside the display area DA as described above. The substrate 100 may include or may be formed of any of various flexible or bendable materials. For example, the substrate 100 may include or may be formed of glass, a metal, or a polymer resin. In an embodiment, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, and cellulose acetate propionate. However, various modifications may be made. For example, the substrate 100 may have a multi-layer structure including two layers each including a polymer resin and a barrier layer including an inorganic material (e.g., silicon oxide, silicon nitride, or silicon oxynitride) and located between the two layers.

A buffer layer 101 may be located on the substrate 100. The buffer layer 101 may function as a barrier layer and/or a blocking layer for preventing diffusion of impurity ions, preventing penetration of moisture or external air, and providing a planarized surface. The buffer layer 101 may include or may be formed of silicon oxide, silicon nitride, or silicon oxynitride. The buffer layer 101 may adjust a heat supply speed during a crystallization process for forming a semiconductor layer 110 so that the semiconductor layer 110 is uniformly crystalized.

The semiconductor layer 110 may be located on the buffer layer 101. The semiconductor layer 110 may be formed of polysilicon, and may include a channel region not doped with impurities and a source region and a drain region formed by doping impurities on opposite sides of the channel region. The impurities may vary according to a type of a thin-film transistor, and may be N-type impurities or P-type impurities.

A gate insulating film 102 may be located on the semiconductor layer 110. The gate insulating film 102 may be an element for ensuring insulation between the semiconductor layer 110 and a gate layer 120. The gate insulating film 102 may include an inorganic material such as silicon oxide, silicon nitride, and/or silicon oxynitride, and may be located between the semiconductor layer 110 and the gate layer 120. The gate insulating film 102 may be formed to correspond to an entire surface of the substrate 100, and may have a structure in which contact holes are formed in preset portions. Such an insulating film including an inorganic material may be formed by using chemical vapor deposition (CVD) or atomic layer deposition (ALD). This applies to the following embodiments and modifications thereof.

A first gate layer 120a may be located on the gate insulating film 102. The first gate layer 120a may vertically overlap the semiconductor layer 110, and may include or may be formed of at least one metal from among molybdenum (Mo), aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (W).

A first interlayer insulating film 103a may be located on the first gate layer 120a.

The first interlayer insulating film 103a may cover the first gate layer 120a. The first interlayer insulating film 103a may include or may be formed of an inorganic material. For example, the first interlayer insulating film 103a may be formed of a metal oxide or a metal nitride. The inorganic material may include silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zirconium oxide (ZrO₂). In an embodiment, the first interlayer insulating film 103a may have a dual structure or double layer of SiOₓ/SiN_{y} or SiNₓ/SiO_{y}.

A second gate layer 120b may be located on the first interlayer insulating film 103a. The second gate layer 120b may vertically overlap the first gate layer 120a, and may include or may be formed of at least one metal from among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (W).

The second gate layer 120b and the first gate layer 120a may constitute the storage capacitor Cst as described with reference to FIG. 2. The first gate layer 120a may be one electrode of the storage capacitor Cst, and the second gate layer 120b may be another electrode of the storage capacitor Cst.

When viewed in a direction perpendicular to the substrate 100, the area of the second gate layer 120b may be greater than the area of the first gate layer 120a. In an embodiment, when viewed in a direction perpendicular to the substrate 100, the second gate layer 120b may cover the first gate layer 120a.

A second interlayer insulating film 103b may be located on the second gate layer 120b. The second interlayer insulating film 103b may cover the second gate layer 120b. The second interlayer insulating film 103b may include or may be formed of an inorganic material. For example, the second interlayer insulating film 103b may be formed of a metal oxide or a metal nitride. The inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zirconium oxide (ZrO₂). In an embodiment, the second interlayer insulating film 103b may have a dual structure or a doubly layer of SiOₓ/SiN_{y} or SiNₓ/SiO_{y} in some embodiments.

A first conductive layer 130 may be located on the second interlayer insulating film 103b. The first conductive layer 130 may function as an electrode connected to the source/drain region of the semiconductor layer through a through-hole formed in the second interlayer insulating film 103b. The first conductive layer 130 may include or may be formed of at least one metal selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the first conductive layer 130 may include or may be a Ti layer, an Al layer, and/or a Cu layer.

A first organic insulating layer 104 may be located on the first conductive layer 130. The first organic insulating layer 104 may cover an upper portion of the first conductive layer 130 and may have a substantially flat top surface. The first organic insulating layer 104 as a planarization film may provide a planarized surface for forming a second organic insulating layer 105, which will be described below. The first organic insulating layer 104 may include or may be formed of, for example, an organic material such as acryl, benzocyclobutene (BCB), and hexamethyldisiloxane (HMDSO). Various modifications may be made. For example, the first organic insulating layer 104 may have a single or multi-layer structure. In an embodiment, the first organic insulating layer 104 may contact the second interlayer insulating film 103b.

The second conductive layer 140 may be located on the first organic insulating layer 104. The second conductive layer 140 may function as an electrode connected to the source/drain region of the semiconductor layer through a through-hole formed in the first organic insulating layer 104. The second conductive layer 140 may include or may be formed of at least one metal selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In an embodiment, the second conductive layer 140 may include or may be a Ti layer, an Al layer, and/or a Cu layer.

A second organic insulating layer 105 may be located on the first conductive layer 130. The second organic insulating layer 105 may cover an upper portion of the first conductive layer 130 and may have a substantially flat top surface. The second organic insulating layer 105 as a planarization film may provide a planarized surface for forming a pixel-defining film 106, which will be described below. The second organic insulating layer 105 may include or may be formed of, for example, an organic material such as acryl, benzocyclobutene (BCB), and hexamethyldisiloxane (HMDSO). Various modifications may be made. For example, the second organic insulating layer 105 may have a single or multi-layer structure.

An organic layer OL may include the first organic insulating layer 104 and the second organic insulating layer 105. In an embodiment, the organic insulating layer OL may further include an additional insulating layer as described below.

Although not shown in FIG. 4, an additional conductive layer and an additional insulating layer may be located between a conductive layer and a pixel electrode, and may be applied in various embodiments. For example, the additional conductive layer and the conductive layer may include the same material and may have the same layer structure. The additional insulating layer and the organic insulating layer may include the same material and have the same layer structure.

A pixel electrode 150 may be located on the second organic insulating layer 105. The pixel electrode 150 may be connected to the second conductive layer 140 through a contact hole formed in the second organic insulating layer 105. A light-emitting layer may be located on the pixel electrode 150. To form the organic light-emitting diode OLED, the light-emitting layer may be located on, for example, the pixel electrode 150. The pixel electrode 150 may include a light-transmitting conductive layer formed of a light-transmitting conductive oxide such as ITO, In₂O₃, and IZO, and a reflective layer formed of a metal such as Al and Ag. For example, the pixel electrode 150 may have a three-layer structure including ITO/Ag/ITO.

The pixel-defining film 106 may be located on the second organic insulating layer 105 to cover an edge of the pixel electrode 150. The pixel-defining film 106 may cover an edge of the pixel electrode 150. The pixel-defining film 106 may have a pixel opening POP corresponding to the pixel PX, and at least a central portion of the pixel electrode 150 may be exposed through the pixel opening POP. The pixel-defining film 106 may include or may be formed of an organic material such as polyimide and hexamethyldisiloxane (HMDSO). In an embodiment, a spacer (not shown) may be located on the pixel-defining film 106.

An intermediate layer 160 and a counter electrode 170 may be located in the pixel opening POP of the pixel-defining film 106. The intermediate layer 160 may include a low molecular weight material or a high molecular weight material. When the intermediate layer 160 includes a low molecular weight material, the intermediate layer 160 may include a hole injection layer, a hole transport layer, an emission layer, an electron transport layer, and/or an electron injection layer. When the intermediate layer 160 includes a high molecular weight material, the intermediate layer 160 may have a structure including a hole transport layer and an emission layer. The intermediate layer 160 may correspond to the light-emitting layer as describe above.

The counter electrode 170 may include a light-transmitting conductive layer formed of a light-transmitting conductive oxide such as ITO, In₂O₃, and IZO. The pixel electrode 150 is used as an anode, and the counter electrode 170 is used as a cathode. Polarities of the electrodes may be applied in reverse.

A structure of the intermediate layer 160 is not limited thereto, and may be any of various structures. For example, at least one of layers constituting the intermediate layer 160 may be integrally formed with the counter electrode 170. In another embodiment, the intermediate layer 160 may include a layer patterned to correspond to each of a plurality of pixel electrodes 150.

The counter electrode 170 may be located in the display area DA, and may be located on an entire surface of the display area DA. The counter electrode 170 may be integrally formed to cover a plurality of pixels. The counter electrode 170 may be in electrical contact with a common power supply line (not shown) located in the peripheral area PA. In an embodiment, the counter electrode 170 may extend to a blocking wall 200. A thin-film encapsulation layer TFE may cover the entire display area DA, and may extend to the peripheral area PA to cover at least a part of the peripheral area PA.

The thin-film encapsulation layer TFE may extend to the outside of the common power supply line (not shown). The thin-film encapsulation layer TFE may include a first inorganic encapsulation layer 310, a second inorganic encapsulation layer 330, and an organic encapsulation layer 320 located between the first inorganic encapsulation layer 310 and the second inorganic encapsulation layer 330. Each of the first and second inorganic encapsulation layers 310 and 330 may include or may be formed of at least one inorganic material from among aluminum oxide, titanium oxide, tantalum oxide, hafnium oxide, zinc oxide, silicon oxide, silicon nitride, and silicon oxynitride.

Each of the first inorganic encapsulation layer 310 and the second inorganic encapsulation layer 330 may have a single or multi-layer structure including the above material. The first inorganic encapsulation layer 310 and the second inorganic encapsulation layer 330 may include or may be formed of the same material or different materials. Thicknesses of the first inorganic encapsulation layer 310 and the second inorganic encapsulation layer 330 may be different from each other. A thickness of the first inorganic encapsulation layer 310 may be greater than a thickness of the second inorganic encapsulation layer 330. Alternatively, a thickness of the second inorganic encapsulation layer 330 may be greater than a thickness of the first inorganic encapsulation layer 310, or thicknesses of the first inorganic encapsulation layer 310 and the second inorganic encapsulation layer 330 may be the same.

The organic encapsulation layer 320 may include or may be formed of a monomer-based material or a polymer-based material. Examples of the polymer-based material may include an acrylic resin, an epoxy resin, polyimide, or polyethylene. In an embodiment, the organic encapsulation layer 320 may include or may be formed of acrylate.

A touch sensing layer YTL may be located on the thin-film encapsulation layer TFE or the second inorganic encapsulation layer 330. The touch sensing layer YTL may have a multi-layer structure. The touch sensing layer YTL includes a sensing electrode, a sensing signal line (trace line) connected to the sensing electrode, and at least one insulating layer. The touch sensor layer YTL may detect an external input by using, for example, a capacitive method. An operation method of the touch sensing layer YTL is not particularly limited to the capacitive method, and in some embodiments, the touch sensing layer YTL may detect an external input by using an electromagnetic induction method or a pressure sensing method.

The touch sensing layer YTL may include a first touch insulating layer 410, a first touch conductive layer MTL1, a second touch insulating layer 420, a second touch conductive layer MTL2, and a third touch insulating layer 430.

The first touch insulating layer 410 may be located on the thin-film encapsulation layer TFE. The first touch insulating layer 410 may include or may be formed of an inorganic material or an organic material and may have a single or multi-layer structure. The organic material may include at least one material selected from the group consisting of an acrylic resin, a methacrylic resin, polyisoprene, a vinyl resin, an epoxy resin, a urethane resin, a cellulose resin, and a perylene resin. The inorganic material may include at least one material selected from the group consisting of silicon nitride (SiN_{X}), aluminum nitride (AlN), zirconium nitride (ZrN), titanium nitride (TiN), hafnium nitride (HfN), tantalum nitride (TaN), silicon oxide (SiO_{X}), aluminum oxide (Al₂O₃), titanium oxide (TiO₂), tin oxide (SnO₂), cerium oxide (CeO₂), and silicon oxynitride (SiON).

The first touch insulating layer 410 may prevent damage to the thin-film encapsulation layer TFE and may block an interference signal that may be generated when the touch sensor layer YTL is driven.

Each of the first touch conductive layer MTL1 and the second touch conductive layer MTL2 may have a single-layer structure or a stacked multi-layer structure. The conductive layer having the single-layer structure may be a metal layer or a transparent conductive layer. The metal layer may include molybdenum (Mo), silver (Ag), titanium (Ti), copper (Cu), aluminum (AI), or an alloy thereof. The transparent conductive layer may include a transparent conductive oxide such as indium tin oxide (ITO), indium zinc oxide (IZO), zinc oxide (ZnO), and indium tin zinc oxide (ITZO). The transparent conductive layer may include a conductive polymer such as PEDOT, metal nanowires, and graphene.

The conductive layer having the multi-layer structure may include multiple metal layers. The multiple metal layers may have, for example, a three-layer structure of Ti/Al/Ti. The conductive layer having the multi-layer structure may include at least one metal layer and at least one transparent conductive layer.

Each of the first touch conductive layer MTL1 and the second touch conductive layer MTL2 includes a plurality of patterns. The first touch conductive layer MTL1 may include first conductive patterns, and the second touch conductive layer MTL2 may include second conductive patterns. The first conductive patterns and the second conductive patterns may form the sensing electrode.

The first touch conductive layer MTL1 and the second touch conductive layer

MTL2 may be electrically connected through a contact hole. In an embodiment, each of the first touch conductive layer MTL1 and the second touch conductive layer MTL2 may have a mesh structure through which light emitted from a lower light-emitting material such as the intermediate layer 160 may pass. In an embodiment, the first touch conductive layer MTL1 and the second touch conductive layer MTL2 may be located so as not to overlap a pattern where the light-emitting material is printed in a plan view.

The second touch insulating layer 420 may include or may be formed of an organic material. The organic material may include at least one material selected from the group consisting of an acrylic resin, a methacrylic resin, polyisoprene, a vinyl resin, an epoxy resin, a urethane resin, a cellulose resin, and a perylene resin. The second touch insulating layer 420 may further include an inorganic material. The inorganic material may include at least one material selected from the group consisting of silicon nitride (SiN_{X}), aluminum nitride (AlN), zirconium nitride (ZrN), titanium nitride (TiN), hafnium nitride (HfN), tantalum nitride (TaN), silicon oxide (SiO_{X}), aluminum oxide (Al₂O₃), titanium oxide (TiO₂), tin oxide (SnO₂), cerium oxide (CeO₂), and silicon oxynitride (SiON).

The third touch insulating layer 430 may be located on the second touch conductive layer MTL2. The third touch insulating layer 430 may have a single or multi-layer structure. The third touch insulating layer 430 may include or may be formed of an organic material, an inorganic material, or a composite material. The inorganic material may include at least one material selected from the group consisting of silicon nitride (SiN_{X}), aluminum nitride (AlN), zirconium nitride (ZrN), titanium nitride (TiN), hafnium nitride (HfN), tantalum nitride (TaN), silicon oxide (SiO_{X}), aluminum oxide (Al₂O₃), titanium oxide (TiO₂), tin oxide (SnO₂), cerium oxide (CeO₂), and silicon oxynitride (SiON). The organic material may include at least one material selected from the group consisting of an acrylic resin, a methacrylic resin, polyisoprene, a vinyl resin, an epoxy resin, a urethane resin, a cellulose resin, and a perylene resin.

A color filter layer or the like for improving the light extraction efficiency of a display element OLED may be further located on the touch sensing layer YTL.

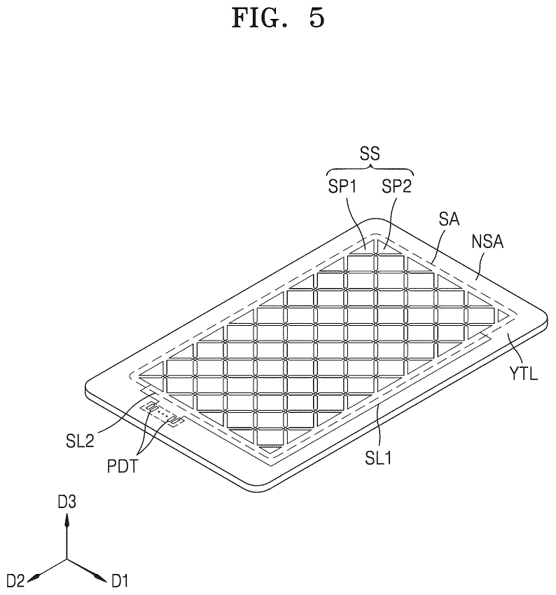

FIG. 5 is a perspective view illustrating a touch sensing layer of the display panel of FIG. 1.

In the description of FIG. 5, the same description as that made above will be omitted.

The touch sensing layer YTL is located on the thin-film encapsulation layer TFE. The touch sensing layer YTL may detect an external input (e.g., a user's touch) and may obtain position or intensity information of the external input. The touch sensing layer YTL may include a plurality of sensing lines (e.g., SL1 and SL2) and a plurality of sensing pads PDT.

The touch sensing layer YTL may include a sensing area SA and a non-sensing area NSA. The sensing area SA may be an area where an external input may be detected. The sensing area SA may overlap the display area DA. In an embodiment, an active area AA may be an area including the sensing area SA and the display area DA.

The non-sensing area NSA is adjacent to the sensing area SA. The non-sensing area NSA may surround an edge of the sensing area SA. However, the present disclosure is not limited thereto. In an embodiment, the non-sensing area NSA may be adjacent to only a part of an edge of the sensing area SA or may be omitted.

A sensing electrode SS is located in the sensing area SA. The sensing electrode

SS may include a first sensing electrode SP1 and a second sensing electrode SP2 which receive different electrical signals. The sensing electrode SS may obtain information about an external input through a change in capacitance between the first sensing electrode SP1 and the second sensing electrode SP2.

The first sensing electrode SP1 extends along the first direction D1. A plurality of first sensing electrodes SP1 may be provided and may be arranged along the second direction D2 to be spaced apart from each other. The second sensing electrode SP2 extends along the second direction D2. A plurality of second sensing electrodes SP2 are provided, and may be arranged along the first direction D1 to be spaced apart from each other.

The sensing lines (e.g., SL1 and SL2) and the sensing pads PDT are located in the non-sensing area NSA. The sensing pads PDT are respectively connected to the sensing lines (e.g., SL1 and SL2). The sensing lines (e.g., SL1 and SL2) include a first sensing line SL1 and a second sensing line SL2. The first sensing line SL1 connects the first sensing electrode SP1 to the first sensing pad PDT to transmit an electrical signal provided from the outside through the sensing pad PDT to the first sensing electrode SP1.

The second sensing line SL2 connects the second sensing electrode SP2 to the sensing pad PDT to transmit an electrical signal provided from the outside through the sensing pad PDT to the second sensing electrode SP2. The sensing pads PDT in the non-sensing area NSA may be electrically connected to other pads (not shown) of the display panel 10.

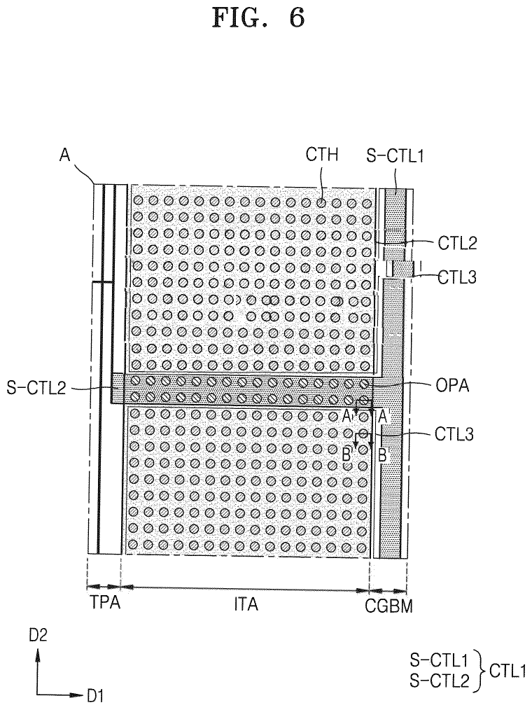

FIG. 6 is a plan view illustrating an example of a portion A of FIG. 2.

In the description of FIG. 6, the same description as that made above will be omitted.

As shown in FIG. 6, in the portion A, a part of the transmitting area TPA, the adjacent area ITA, and a part of the light-blocking area CGBM of the window member 20 may be located. In the portion A, a part of the display area DA and a part of the peripheral area PA may be located.

In the portion A, a first metal wiring CTL1 and a second metal wiring CTL2 may be located. The first metal wiring CTL1 may be located on the display panel 10 and may extend in one direction. The second metal wiring CTL2 may be located on the first metal wiring CTL1 and may extend in another direction. The one direction and the other direction may intersect each other in a plan view. For example, the one direction may be the second direction D2 and the other direction may be the first direction D1.

In an embodiment, the first metal wiring CTL1 may include a first sub-metal wiring S-CTL1 and a second sub-meal wiring S-CTL2 connected thereto. For example, a part of the first metal wiring CTL1 may be the first sub-metal wiring S-CTL1. The first sub-metal wiring S-CTL1 may extend in one direction (e.g., the second direction D2) in the light-blocking area CGBM.

Another part of the first metal wiring CTL1 may be the second sub-metal wiring S-CTL2. The second sub-metal wiring S-CTL2 may extend from the first sub-metal wiring S-CTL1 in the other direction (e.g., the first direction D1). The second sub-metal wiring S-CTL2 may extend from the light-blocking area CGBM through the adjacent area ITA toward the transmitting area TPA.

In an embodiment, the second metal wiring CTL2 may include a plurality of contact holes CTH. In an embodiment, the second metal wiring CTL2 may include a plurality of openings OPA.

For example, the first metal wiring CTL1 may be a touch wiring, and the second metal wiring CTL2 may be a ground wiring. Because the second metal wiring CTL2 is a ground wiring, a width of the second metal wiring CTL2 may be greater than a width of the first metal wiring CTL1 in some cases.

In an embodiment, the first metal wiring CTL1 and the first touch conductive layer MTL1 may be located on the same layer and may have the same layer structure. In an embodiment, the first metal wiring CTL1 and the first touch conductive layer MTL1 may be formed from a same metal layer. In an embodiment, the first metal wiring CTL1 and the first touch conductive layer MTL1 may be formed at a same height with reference to an upper surface of the substrate 100. In an embodiment, the second metal wiring CTL2 and the second touch conductive layer MTL2 may be located on the same layer and may have the same layer structure. In an embodiment, the second metal wiring CTL2 and the second touch conductive layer MTL2 may be formed from a same metal layer. In an embodiment, the second metal wiring CTL2 and the second touch conductive layer MTL2 may be formed at a same height with reference to the upper surface of the substrate 100.

The touch sensing layer YTL may further include a third metal wiring CTL3 that is located on the same layer and has the same layer structure as the first metal wiring CTL1. In an embodiment, the third metal wiring CTL3 and the first metal wiring CTL1 may be formed from a same metal layer. In an embodiment, the third metal wiring CTL3 and the first metal wiring CTL1 may be formed at a same height with reference to an upper surface of the substrate 100.

The second touch insulating layer 420 may also be referred to as insulating member layer 420. The insulating member layer 420 may include the contact hole CTH passing through the insulating member layer 420. The contact hole CTH may be located in an overlapping area (i.e., a second region) where the third metal wiring CTL3 and the second metal wiring CTL2 overlap each other in a plan view. The contact hole CTH may be located in the adjacent area ITA. The third metal wiring CTL3 and the second metal wiring CTL2 may directly contact each other through the contact hole CTH. In an embodiment, the third metal wiring CTL3 may be connected to the second metal wiring CTL2 through the contact hole CTH. For example, a conductive contact via filling the contact hole CTH may connect the third metal wiring CTL3 to the second metal wiring CTL2. The insulating member layer 420 may be one of the touch insulating layers. For example, the insulating member layer 420 may be the second touch insulating layer.

For example, the second metal wiring CTL2 and the third metal wiring CTL3 may transmit the same signal, and the second metal wiring CTL2 and the first metal wiring CTL1 may transmit different signals.

For example, the third metal wiring CTL3 and the first touch conductive layer MTL1 may be located on the same layer and may have the same layer structure. In an embodiment, the third metal wiring CTL3 and the first touch conductive layer MLT1 may be formed from a same metal layer. In an embodiment, the third metal wiring CTL3 and the first touch conductive layer MLT1 may be formed at a same height with reference to an upper surface of the substrate 100.

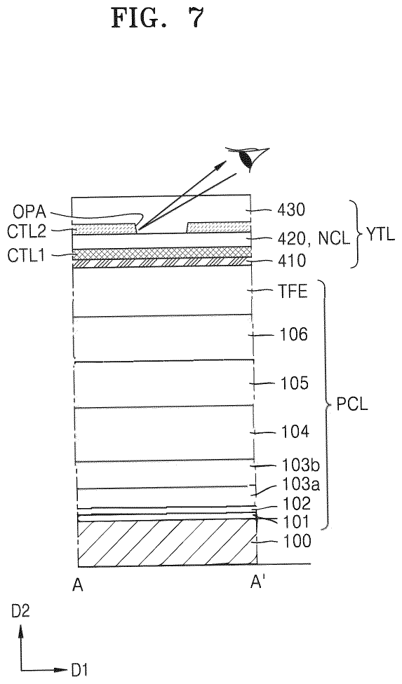

FIG. 7 is a cross-sectional view taken along line A-A′ of FIG. 6.

In the description of FIG. 7, the same description as that made above will be omitted. FIG. 6 shows a portion located in the adjacent area ITA. The cross-sectional view of FIG. 7 illustrates the opening OPA located in the adjacent area ITA. For convenience of explanation, the window member 20 is not shown in the cross-sectional view of FIG. 7.

As shown in FIG. 7, the display apparatus according to an embodiment may include the substrate 100, the pixel circuit layer PCL located on the substrate 100, and the touch sensing layer YTL located on the pixel circuit layer PCL.

In the adjacent area ITA, the touch sensing layer YTL may include the first metal wiring CTL1 extending in one direction, the insulating member layer 420 located on the first metal wiring CTL1, and the second metal wiring CTL2 located on the insulating member layer 420 and extending in another direction.

The second metal wiring CTL2 may include the opening OPA through which a top surface of the insulating member layer 420 is exposed upward. The opening OPA may be provided in plural, and the second metal wiring CTL2 may include a plurality of openings OPA. The opening OPA may be located at an intersection area (i.e., a first region) where the second metal wiring CTL2 and the first metal wiring CTL1 intersect each other in a plan view. For example, the intersection area may be an area where the second sub-metal wiring S-CTL2 and the first metal wiring CTL1 intersect each other in a plan view.

In an embodiment, the opening OPA may be located at an intersection area where the first metal wiring CTL1 and the second metal wiring CTL2 intersect each other in the adjacent area ITA. When a user looks at the display apparatus, due to a metallic wiring located in the adjacent area ITA, the adjacent area ITA may be easily viewed by a user as a relatively dark color. To prevent this, the contact hole CTH as described below may be formed in a top surface of the second metal wiring CTL2 located in the adjacent area. However, because the contact hole CTH forms an electrical contact between metal wirings that are vertically located, the contact hole CTH may be applied only when signals transmitted through the vertically located metal wirings are the same signal. Accordingly, when signals transmitted through the vertically located metal wirings are different signals, it is preferable to use the opening OPA than the contact hole CTH.

There may be a plurality of openings OPA, and for example, each of the plurality of openings OPA may have a circular shape and/or an elliptical shape in a plan view. Each of the plurality of openings OPA may have any of various shapes in a plan view. However, considering the difficult of a pattern forming process, a shape of each of the plurality of openings OPA may be a circular shape and/or an elliptical shape in a plan view.

As shown in FIG. 7, external light may be reflected from an inner surface of the opening OPA. Accordingly, the adjacent area ITA may be brighter due to the opening OPA.

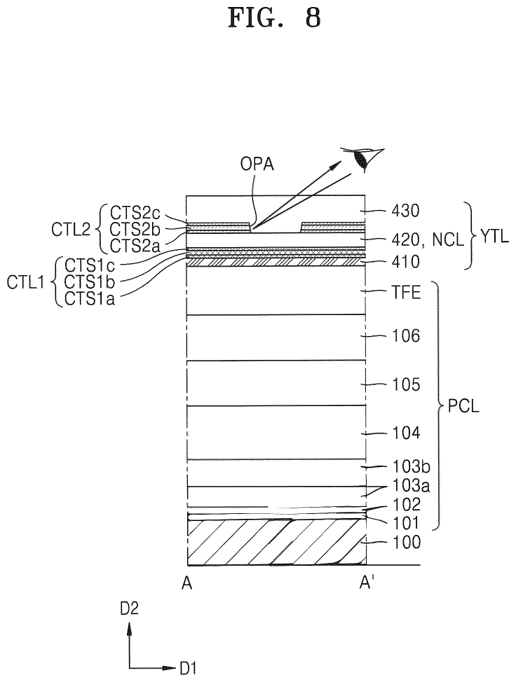

FIG. 8 is a cross-sectional view taken along line A-A′ of FIG. 6.

In the description of FIG. 8, the same description as that made above will be omitted. FIG. 6 shows a portion located in the adjacent area ITA, and the cross-sectional view of FIG. 8 illustrates the opening OPA located in the adjacent area ITA. For convenience of explanation, the window member 20 is not shown in the cross-sectional view of FIG. 8.

As shown in FIG. 8, the second metal wiring CTL2 may include a first layer CTS2a including a first metal, a second layer CTS2b including a second metal and located on the first layer CTS2a, and a third layer CTS2c including the first metal and located on the second layer CTS2b. For example, the second metal wiring CTL2 may have three layers, and the first metal may be Ti and the second metal may be Al.

The second metal wiring CTL2 may include the opening OPA, and each of the first layer CTS2a, the second layer CTS2b, and the third layer CTS2c may include a sub-opening. Inner surfaces of the sub-openings of the first layer CTS2a, the second layer CTS2b, and the third layer CTS2c may be continuous surfaces, and the sub-openings of the first layer CTS2a, the second layer CTS2b, and the third layer CTS2c may form one opening OPA.

An inner surface of the opening OPA may include one side surface of the first layer CTS2a, one side surface of the second layer CTS2b located on the one side surface of the first layer CTS2a, and one side surface of the third layer CTS2c located on the one side surface of the second layer CTS2b. For example, one side surface of the first layer CTS2a, one side surface of the second layer CTS2b, and one side surface of the third layer CTS2c may form a continuous surface.

The first metal wiring CTL1 may include a 1-1 sub-layer CTS1a including a first metal, a 1-2 sub-layer CTS1b including a second metal and located on the 1-1 sub-layer CTS1a, and a 1-3 sub-layer CTS1c including the first metal and located on the 1-2 sub-layer CTS1b. For example, the first metal wiring CTL1 may have three layers, and the first metal may be Ti and the second metal may be Al.

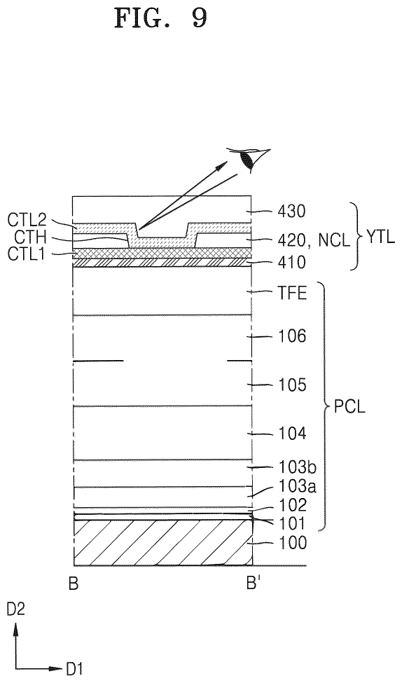

FIG. 9 is a cross-sectional view taken along line B-B′ of FIG. 6.

In the description of FIG. 9, the same description as that made above will be omitted. FIG. 6 shows a portion located in the adjacent area ITA. The cross-sectional view of FIG. 9 illustrates the contact hole CTH located in the adjacent area ITA. For convenience of explanation, the window member 20 is omitted in the cross-sectional view of FIG. 9.

As shown in FIG. 9, the insulating member layer 420 may include the contact hole CTH passing through the insulating member layer 420. The contact hole CTH may be located in an area where the third metal wiring CTL3 and the second metal wiring CTL2 overlap each other in a plan view. For example, the third metal wiring CTL3 and the second metal wiring CTL2 may directly contact each other through the contact hole CTH.

The second metal wiring CTL2 and the third metal wiring CTL3 may transmit the same signal, and the second metal wiring CTL2 and the first metal wiring CTL1 may transmit different signals. Because metal wirings contact each other through the contact hole CTH, metal wirings in an area where the contact hole CTH is located need to be wirings that transmit the same signal. Wirings transmitting different signals may not be connected with each other using the contact hole CTH. The contact hole CTH may be located in the adjacent area ITA in a plan view.

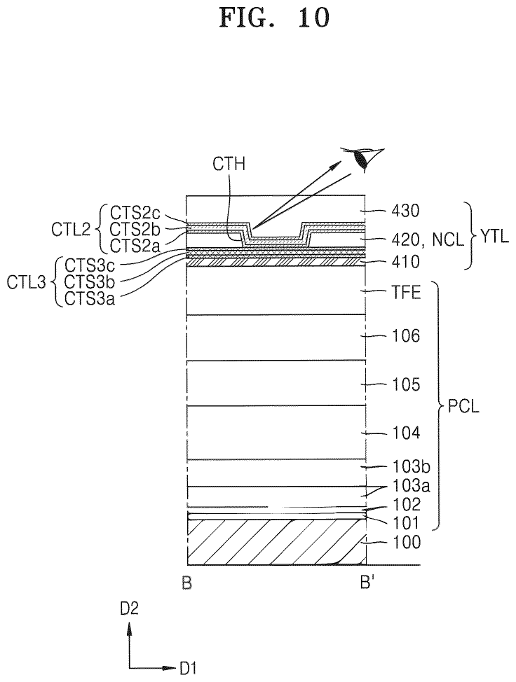

FIG. 10 is a cross-sectional view taken along line B-B′ of FIG. 6.

In the description of FIG. 10, the same description as that made above will be omitted. FIG. 6 shows a portion located in the adjacent area ITA. The cross-sectional view of FIG. 10 illustrates the contact hole CTH located in the adjacent area ITA. For convenience of explanation, the window member 20 is not shown in the cross-sectional view of FIG. 10.

As shown in FIG. 10, the third metal wiring CTL3 may include a 2-1 sub-layer CTS3a including a first metal, a 2-2 sub-layer CTS3b including a second metal and located on the 2-1 sub-layer CTS3a, and a 2-3 sub-layer CTS3c including the first metal and located on the 2-2 sub-layer CTS3b. For example, the third metal wiring CTL3 may have three layers, and the first metal may be Ti and the second metal may be Al.

The 2-3 sub-layer CTS3c and the second metal wiring CTL2 may directly contact each other through the contact hole CTH. The 2-3 sub-layer CTS3c and the 1-1 sub-layer CTS2a of the second metal wiring CTL2 may directly contact each other through the contact hole CTH.

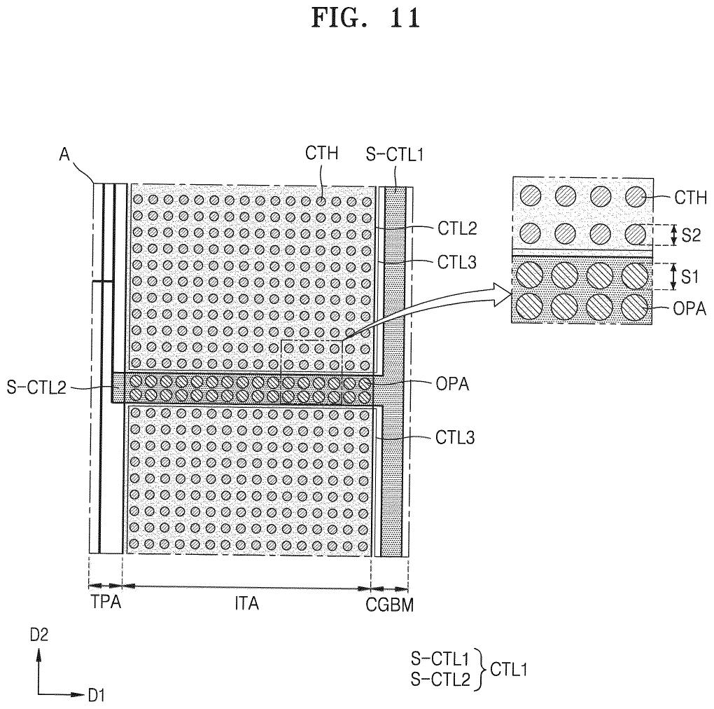

FIGS. 11 to 13 are plan views illustrating an example of the portion A of FIG. 2.

In the description of FIGS. 11 to 13, the same description as that made above will be omitted.

As shown in FIG. 11, a diameter of the contact hole CTH may be less than a diameter of the opening OPA in a plan view. A diameter of the opening OPA may be greater than a diameter of the contact hole CTH in a plan view.

The area of an inner surface of the contact hole CTH may be greater than the area of an inner surface of the opening OPA. Accordingly, to match the amount of reflection of external light, a diameter of the opening OPA may be greater than a diameter of the contact hole CTH in a plan view. This is because, as a diameter increases, the area of an inner surface also increases.

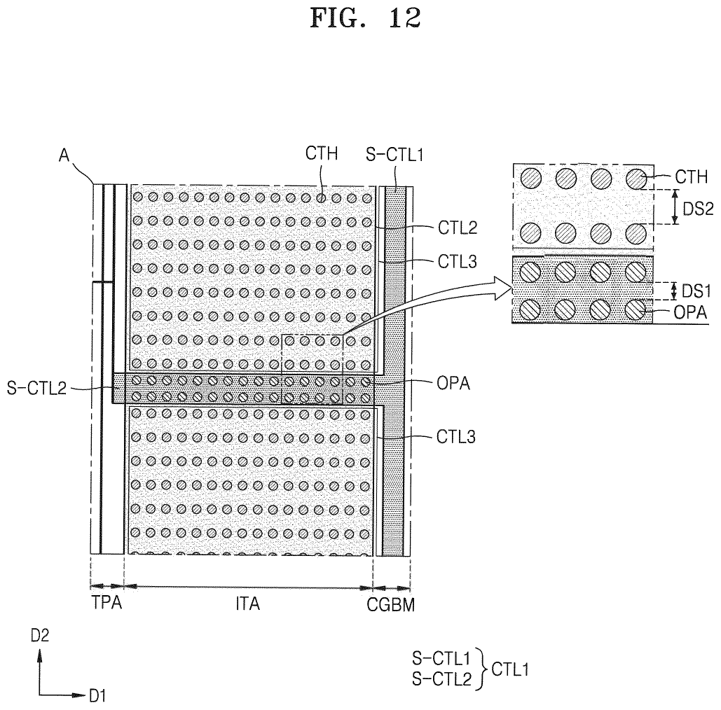

As shown in FIG. 12, a distance between the contact holes CTH may be greater than a distance between the openings OPA in a plan view. A distance between the openings OPA may be greater than a distance between the contact holes CTH in a plan view.

For example, a distance between the contact holes CTH may be a distance in the second direction D2. A distance between the openings OPA may also be a distance in the second direction D2.

The area of an inner surface of the contact hole CTH may be greater than the area of an inner surface of the opening OPA. Accordingly, to match the amount of reflection of external light, a distance between the contact holes CTH may be greater than a distance between the openings OPA in a plan view. As a distance decreases in a plan view, the density of the contact holes CTH or the openings OPA may increase. This is because, as the density of the contact holes CTH or the openings OPA increases, more external light is reflected.

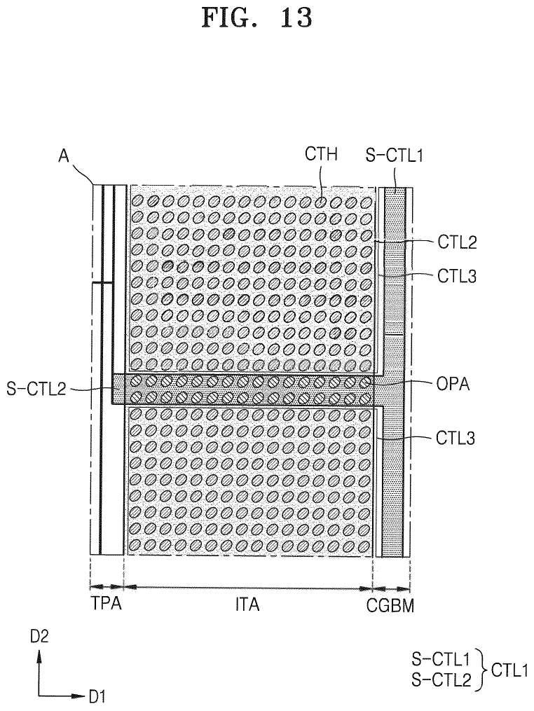

As shown in FIG. 13, the contact hole CTH and/or the opening OPA may have an elliptical shape in a plan view. In FIGS. 11 and 12, the contact hole CTH and/or the opening OPA may have a circular shape in a plan view. As such, the contact hole CTH and/or the opening OPA may have any of various shapes in a plan view.

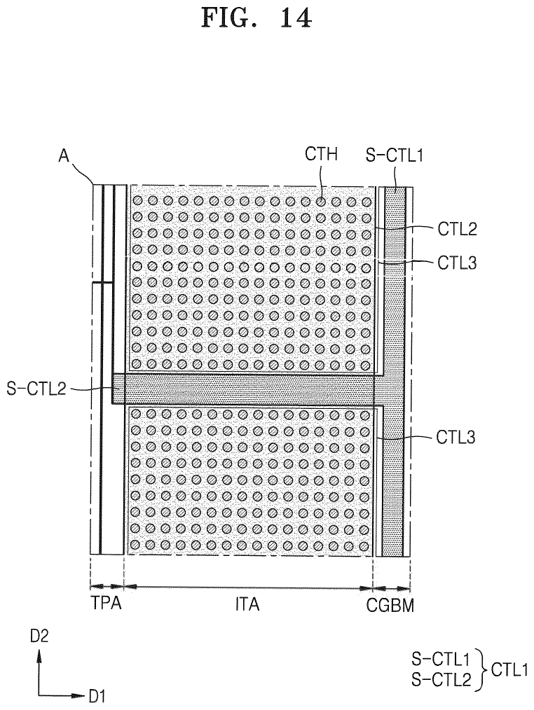

FIG. 14 is a plan view illustrating an example of a portion of a display apparatus according to a comparative example, which corresponds to the portion A of FIG. 2.

In the description of FIG. 14, the same description as that made above will be omitted.

As shown in FIG. 14, the display apparatus according to the comparative example may include only the contact hole CTH. As described above, the contact hole CTH may be located only an area where the second metal wiring CTL2 and the third metal wiring CTL3 overlap each other in the adjacent area ITA. The contact hole CTH may not be located in an area where the second metal wiring CTL2 and the first metal wiring CTL1 intersect each other in the adjacent area ITA.

Accordingly, when a user looks at the display apparatus, a portion of the adjacent area ITA where the contact hole CTH is not located may be darker than other portions. This may adversely affect the display quality perceived by the user.

While some embodiments have been described, it will be understood by one of ordinary skill in the art that various changes in form and details may be made therein without departing from the spirit and scope of the disclosure. Unless described otherwise, descriptions of features or aspects within each embodiment should be typically be considered as available for other similar features or aspects in other embodiments. Accordingly, as is apparent to one of ordinary skill in the art, features or components described with respect to a particular embodiment may be combined with features or components described with respect to other embodiments. Hence, the foregoing should not be construed as being limited to the specific embodiments disclosed herein, but should be understood as being intended for combination with or application to other embodiments. Accordingly, the true technical scope of the present disclosure should be defined by the technical spirit of the appended claims.

According to an embodiment as described above, a display apparatus that minimizes dark patterns generated by a metal wiring of a touch sensing layer may be provided. However, the scope of the present disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display apparatus comprising:
a substrate;
a pixel circuit layer located on the substrate; and
a touch sensing layer located on the pixel circuit layer, and comprising a first metal wiring, an insulating member layer located on the first metal wiring, and a second metal wiring located on the insulating member layer,
wherein the second metal wiring comprises an opening exposing a top surface of the insulating member layer, and
wherein the opening of the second metal wiring is located at a first region where the second metal wiring and the first metal wiring overlap each other in a plan view.

2. The display apparatus of claim 1,
wherein the second metal wiring further comprises:
a first layer comprising a first metal;
a second layer comprising a second metal and located on the first layer; and
a third layer comprising the first metal and located on the second layer.

3. The display apparatus of claim 2,
wherein an inner surface of the opening comprises:
a first inner side surface of the first layer;
a second inner side surface of the second layer; and
a third inner side surface of the third layer, and
wherein the first inner side surface, the second inner side surface, and the third inner side surface are coplanar with other to form the inner surface of the opening.

4. The display apparatus of claim 1,
wherein the opening is provided in plural,
wherein each of the plurality of openings has a circular shape or an elliptical shape in a plan view.

5. The display apparatus of claim 1,
wherein the touch sensing layer further comprises:
a third metal wiring located on a same layer and having a same layer structure as the first metal wiring.

6. The display apparatus of claim 5,
wherein the insulating member layer comprises a contact hole passing through the insulating member layer and located at a second region where the third metal wiring and the second metal wiring overlap each other.

7. The display apparatus of claim 6,
wherein the third metal wiring is connected to the second metal wiring via the contact hole.

8. The display apparatus of claim 6,
wherein the second metal wiring and the third metal wiring are configured to transmit a same signal, and
wherein the second metal wiring and the first metal wiring are configured to transmit different signals.

9. The display apparatus of claim 6, further comprising
a window member located on the touch sensing layer,
wherein the window member comprises a transmitting area, a light-blocking pattern covering an edge of the window member, and an adjacent area therebetween.

10. The display apparatus of claim 9,
wherein the substrate comprises a display area where an image is displayed and a peripheral area covered by the light-blocking pattern and the adjacent area,
wherein the display area is covered by the transmitting area, and
wherein the opening is located in the adjacent area in a plan view.

11. The display apparatus of claim 10,
wherein the contact hole is located in the adjacent area.

12. The display apparatus of claim 6,
wherein a first diameter of the opening is greater than a second diameter of the contact hole in a plan view.

13. The display apparatus of claim 6,
wherein the opening is provided in plural, and the contact hole is provided in plural,
wherein a first distance between two adjacent openings among the plurality of openings is less than a second distance between two adjacent contact holes among the plurality of contact holes in a plan view, and
wherein the first distance and the second distance are measured in a same direction.

14. The display apparatus of claim 10,
wherein the second metal wiring further comprises:
a first sub-metal wiring disposed in the peripheral area; and
a second sub-metal wiring disposed in the adjacent area.

15. The display apparatus of claim 14,
wherein the first region is an area where the second sub-metal wiring and the first metal wiring intersect each other in a plan view.

16. The display apparatus of claim 14, further comprising
a window member located on the touch sensing layer,
wherein the window member comprises a light-blocking pattern covering an edge of the window member,
wherein the light-blocking pattern overlaps the first sub-metal wiring in a plan view.

17. The display apparatus of claim 6,
wherein the third metal wiring comprises:
a 2-1 sub-layer comprising a first metal;
a 2-2 sub-layer comprising a second metal and located on the 2-1 sub-layer; and
a 2-3 sub-layer comprising the first metal and located on the 2-2 sub-layer.

18. The display apparatus of claim 17,
wherein the 2-3 sub-layer is connected to the second metal wiring through the contact hole.

19. The display apparatus of claim 1,
wherein the pixel circuit layer comprises at least one light-emitting device and a thin-film encapsulation layer on the at least one light-emitting device, and
wherein the touch sensing layer is located on the thin-film encapsulation layer.

20. The display apparatus of claim 1,
wherein the second metal wiring is a ground wiring.
